(19) United States
(12) Patent Application Publication
(10) Pub. No.: US 2012/0153307 A1
(43) Pub. Date: Jun. 21, 2012

(54) LED LIGHTING DEVICE WITH EXCELLENT HEAT DISSIPATION PROPERTY

(75) Inventor: Tsan-Jung Chen, Sanchung City (TW)

(73) Assignee: KOCAM INTERNATIONAL CO., LTD., Sanchung City (TW)

(21) Appl. No.: 12/970,947

(22) Filed: Dec. 17, 2010

(51) Int. Cl. H01L 27/15

(52) U.S. Cl. 257/88; 257/E27.12

(57) ABSTRACT

The present invention relates to an improved LED lighting device with good heat dissipation, comprising: a housing; a copper circuit layer, disposed on the housing; a plurality of LED chips, disposed on the copper circuit layer; and a white reflective member, disposed on the plurality of LED chips and the copper circuit layer, wherein the white reflective member is used to increase the light-emitting efficiencies of the LED chips. In the present invention, the copper circuit layer is directly disposed on the housing without using an aluminum substrate or a print circuit board, so that the cost of the improved LED lighting device is reduced; moreover, that also prevents the LED chips from damage when welding the LED chips, and makes the improved LED lighting device performing better heat dissipation property.

### BACKGROUND OF THE INVENTION

1. Technical Field

The present invention relates to an LED lighting device, and more particularly, to an improved LED lighting device with excellent heat dissipation property, which has the property of low manufacturing cost and capable of prevent the LED chips from damage.

2. Description of Related Art

Recently, LED (light-emitting diode) chips are widely used in illumination apparatuses of human life. However, it is easily to produce high heat when the LED chips emit light. For this reason, a conventional LED lighting device generally includes at least one material or device used for heat dissipation.

Please refer to FIG. 1, which illustrated an exploded view of a conventional LED lighting device. As shown in FIG. 1, the conventional LED lighting device 1′ includes: a housing 11′ and a carrying substrate 12′, wherein the carrying substrate 12′ is disposed on the housing 11′ through a thermal conductive adhesion 14′, and is used for carrying a plurality of LED chips 13′. The carrying substrate 12′ is commonly a metal substrate or a ceramics substrate. When using the metal substrate as the carrying substrate 12′, which includes an aluminum substrate 122′ and a copper circuit layer 123′, wherein the copper circuit layer 123′ is used for electrically receiving and connecting the LED chips 13′, and the aluminum substrate 122′ has a thermal conductive property for conducting the heat produced by LED chips 13′ to the housing 11′. The thermal conductive adhesion also coated between the aluminum substrate 122′ and the copper circuit layer 123′ for preventing from electrical short. Besides, as shown in FIG. 1, a white paint 121′ is coated on the surface of the aluminum substrate 122′ and adopted for reflect the light emitted by the LED chips 13′, so as to increase the light-emitting efficiencies of the LED chips 13′.

The housing 11′ is a metal with the thermal conductive property, and a plurality of heat-dissipating structures 15′ are disposed on the outer side-surface of the housing 11′. Thus, when the LED chips 13′ emit light, the heat produced by the LED chips 13′ is conducted to the housing 11′ through the aluminum substrate 122′ and dissipated via the heat dissipation structures 15′. The housing 11′ further includes a control circuit module in the inside thereof used for controlling the LED chips 13′ to emit light.

For the conventional LED lighting device 1′, the LED chips 13′ are disposed on the carrying substrate 12′ by means of welding. When welding the LED chips 13′ on the copper circuit layer 123′ of the carrying substrate 12′, it firstly coats a solder paste onto the copper circuit layer 123′; then, disposing the LED chips 13′ on the copper circuit layer 123′ by way of surface mount; and then, using a heat wind to blow and melt the solder paste, so that the LED chips 13′ are mounted on the copper circuit layer 123′ after cooling the solder paste.

Thus, according to the above description, it is easily to know that the conventional LED lighting device 1′ is widely used in human life and has good heat dissipation property; besides, the way of welding the LED chips 13′ on the copper circuit layer 123′ is simple. However, the conventional LED lighting device 1′ still includes shortcomings and drawbacks as follows:
1. When using the heat wind to blow and melt the solder paste, the LED chips are damaged due to high temperature of the heat wind, so that the light-emitting quality of the LED lighting device 1′ is reduced.
2. Inheriting to above point 1, when the solder paste is in melted state, to continuously blow the solder paste and the LED chips 13′ causes the displacement of partial LED chips 13′, such that the displaced LED chips 13′ fail to emit light.
3. The LED chips 13′ are disposed on the housing 11′ through the carrying substrate 12′, however, there are commonly existing gaps between the carrying substrate 12′ and the housing 11′, and the air in the gaps produces a thermal resistance which reduces the thermal conductivity between the carrying substrate 12′ and the housing 11′, so that the heat produced by the LED chips 13′ can not be effectively conducted to the housing 11′ and dissipated by the heat-dissipating structures 15′.

Accordingly, in view of the conventional LED lighting device still has shortcomings and drawbacks, the inventor of the present application has made great efforts to make inventive research thereon and eventually provided an improved LED lighting device with excellent heat dissipation property.

### BRIEF SUMMARY OF THE INVENTION

The primary objective of the present invention is to provide an improved LED lighting device with excellent heat dissipation property, in which a copper circuit layer is directly disposed on a housing of the improved LED lighting device without using an aluminum substrate or a print circuit board, so as to prevent a plurality of LED chips from damage when welding the LED chips on the copper circuit layer, and makes the improved LED lighting device performing better heat dissipation property, moreover the cost of the LED lighting device is reduced.

Accordingly, to achieve the abovementioned primary objective, the inventor proposes an improved LED lighting device with excellent heat dissipation property, comprising: a housing, having at least one control circuit module in the inside and having a plurality heat dissipation structures in the outside; a copper circuit layer, disposed on the housing and electrically connected to the control circuit module; a plurality of LED chips, disposed on the copper circuit layer, so that the control circuit module is able to control the light emitting of the LED chips; and a white reflective member, having a plurality of holes, so that the LED chips pass the holes respectively when the white reflective member is disposed on the copper circuit layer; moreover, through the white reflective member, the light-emitting efficiencies of the LED chips are increased.

### BRIEF DESCRIPTION OF THE SEVERAL VIEWS OF THE DRAWINGS

The invention as well as a preferred mode of use and advantages thereof will be best understood by referring to the following detailed description of an illustrative embodiment in conjunction with the accompanying drawings, wherein:

FIG. 1 is an exploded view of a conventional LED lighting device;

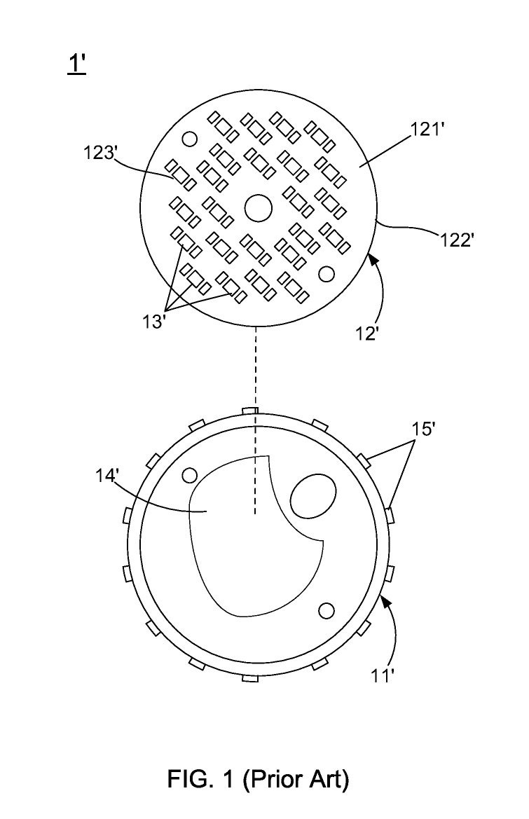

FIG. 2 is a stereo view of an improved LED lighting device with excellent heat dissipation property according to the present invention; and

FIG. 3 is the stereo view of a second embodiment of the improved LED lighting device with excellent heat dissipation property according to the present invention.

### DETAILED DESCRIPTION OF THE INVENTION

To more clearly describe an improved LED lighting device with excellent heat dissipation property according to the present invention, embodiments of the present invention will be described in detail with reference to the attached drawings hereinafter.

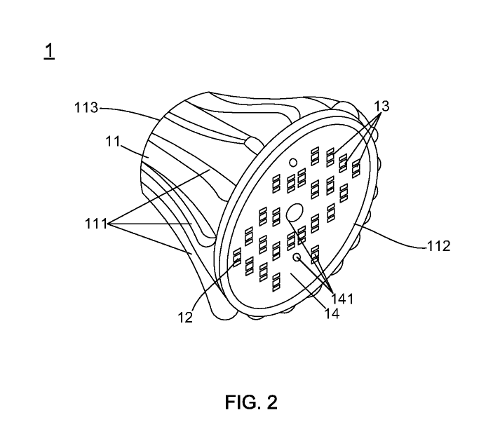

Please refer to FIG. 2, which illustrated a stereo view of an improved LED lighting device with excellent heat dissipation property according to the present invention. As shown in FIG. 2, the improved LED lighting device 1 includes: a housing 11, a copper circuit 12, a plurality of LED chips 13, a thermal conductive adhesion, and a white reflective member 14 (in FIG. 2, since the thermal conductive adhesion is covered by the white reflective member 14, it is not shown in FIG. 2.). The housing 11 is a metal with a thermal conductive property, and a plurality of fin structures 111 are disposed on the outer side-surface of the housing 11 adopted for dissipating heat; Moreover, a large round surface 112 and a small round surface 113 are formed on the two ends of the housing 11. The housing 11 further has at least one control circuit module in the inside thereof (the control circuit module is belonged to the conventional technology and not the subject matter of the technology of the present invention, so that, it is not shown in FIG. 2).

Referring to FIG. 2 again, the copper circuit layer 12 is disposed on the large round surface 112 of the housing 11 and capable of electrically connecting the control circuit module. As shown in FIG. 2, the copper circuit layer 12 includes a plurality of small rectangular sections adopted for respectively receiving and connecting the plurality of LED chips 13. In the embodiment of the improved LED lighting device 1, the LED chips 13 are welded on the copper circuit layer 12, so that the control circuit module may control the LED chips 13 to emit light. The thermal conductive adhesion is coated between the LED chips 13 and used for prevent two adjacent LED chips 13 from electrical short; moreover, through the thermal conductive adhesion, the white reflective member 14 is affixed on the copper circuit layer 12. The white reflective member 14 has a plurality of holes 141, which are used for allowing the LED chips 13 to pass through when the white reflective member 14 is affixed on the copper circuit layer 12. Thereof, by way of the white reflective member 14, the light-emitting efficiencies of the LED chips are increased.

Distinguishing from the conventional LED lighting device, in the improved LED lighting device 1 of the present invention, the copper circuit layer 12 is directly disposed on the housing 11 without using an aluminum substrate or a print circuit board, so that the cost of the improved LED lighting device 1 is reduced. Furthermore, when the LED chips 13 on the copper circuit layer 12 emit light, the heat produced by the LED chips 13 can be directly conducted to the fin structures through the housing 11 for being effectively dissipated. In addition, compared with the conventional LED lighting device, the manufacturing procedures of the improved LED lighting device 1 of the present invention is uncomplicated, the manufacturing procedures of the improved LED lighting device 1 includes the steps of: (1) coating a solder paste onto the copper circuit layer 12; (2) disposing the LED chips 13 on the copper circuit layer 12 by using a carrying apparatus; (3) melting the solder paste by heating the housing 11; (4) cooling the solder paste. Thereof, the LED chips 13 are easily welded on the copper circuit layer 12 after the above four manufacturing steps are finished.

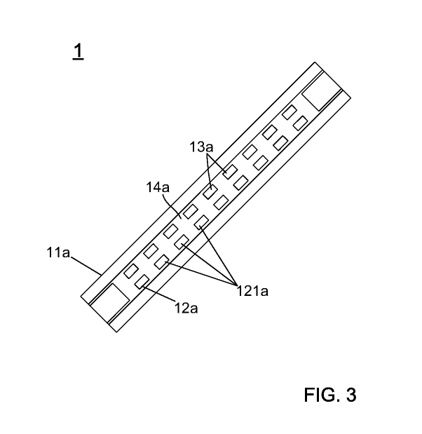

For increasing the application of the improved LED lighting device 1 with excellent heat dissipation property, a second embodiment of the improved LED lighting device 1 is disclosed in the present invention. Please refer to FIG. 3, which illustrated the stereo view of the second embodiment of the improved LED lighting device with excellent heat dissipation property according to the present invention. The same to the first embodiment, as shown in FIG. 3, the second embodiment of the improved LED lighting device 1 includes: a housing 11a, a copper circuit layer 12a, a plurality of LED chips 13a, a thermal conductive adhesion, and a white reflective member 14a (in FIG. 3, the thermal conductive adhesion is covered by the white reflective member 14, so that, it is not shown in FIG. 3.). The housing 11a is also a metal with thermal conductive property, and the appearance of housing 11a is designed to the conventional long-shaped housing; moreover, a plurality of fin structures are disposed on the outer side-surface of the housing 11a adopted for heat dissipation (the fin structures are formed on another surface of the housing 11a, so that the fin structures are not shown in FIG. 3.). Besides, the same to the first embodiment of the improved LED lighting device 1, there is a control circuit module disposed in the housing 11a used for controlling the LED chips to emit light.

Referring to FIG. 3, the copper circuit layer 12a is disposed on the surface of the housing 11a and electrically connected to the control circuit module. The copper circuit layer 12a has a plurality of small rectangular decoctions 121a for receiving the LED chips 13a. The LED chips 13a is disposed on the copper circuit layer 12a by way of welding, so that the control circuit module is able to control the LED chips 13a to emit light. The thermal conductive adhesion is coated on the copper circuit layer 12a; thus, through the thermal conductive adhesion, the white reflective member 14a is affixed on the copper circuit layer 12a and used to increase the light-emitting efficiencies of the LED chips 13a.

Thus, through the above descriptions, the improved LED lighting device with excellent heat dissipation property of the present invention has been disclosed completely and clearly in the above description. In summary, the present invention has the following advantages:
1. Since the improved LED lighting device not includes the aluminum substrate or the print circuit board between the LED chips and the housing, the LED chips can be welded on the copper circuit layer by means of directly heating the housing and melting the solder paste; furthermore, when welding the LED chips onto the copper circuit layer, it is able to prevent the LED chips from damage caused by directly heating.
2. Inheriting to above point 1, for the LED chips are welded on the copper circuit layer by means of directly heating the housing and melting the solder paste, the phenomena of partial LED chips being displaced can also be avoided, so that all LED chips in the improved LED lighting device are able to emit light successfully.
3. The copper circuit layer is directly disposed on the metal housing without using the aluminum substrate or the print circuit board; thus, there are no gaps existing between the copper circuit layer and the metal housing; for this reason, when the LED chips emit light, the heat produced by the LED chips are directly conducted to the fin structures through the metal housing for being effectively dissipated.
4. Inheriting to above point 3, copper circuit layer is directly disposed on the metal housing without using the aluminum substrate or the print circuit board, the cost of the improved LED lighting device is reduced.

The above description is made on embodiments of the present invention. However, the embodiments are not intended to limit scope of the present invention, and all equivalent implementations or alterations within the spirit of the present invention still fall within the scope of the present invention.

I claim:

1. An improved LED lighting device with excellent heat dissipation property, comprising:
a housing, having at least one control circuit module in the inside and a plurality heat dissipation structures in the outside thereof;
a copper circuit layer, being disposed on the housing and electrically connected to the control circuit module;
a plurality of LED chips, being disposed on the copper circuit layer, so that the control circuit module is able to control the light emitting of the LED chips; and
a white reflective member, having a plurality of holes, wherein the LED chips pass the holes respectively when the white reflective member is disposed on the copper circuit layer; moreover, through the white reflective member, the light-emitting efficiencies of the LED chips being increased.

2. The improved LED lighting device with excellent heat dissipation property of claim 1, further comprising a thermal conductive adhesion, being coated between the plurality of LED chips and the copper circuit layer.

3. The improved LED lighting device with excellent heat dissipation property of claim 1, wherein the housing is a metal with thermal conductive property.

4. The improved LED lighting device with excellent heat dissipation property of claim 1, wherein a solder paste on the copper circuit layer can be melted through heating the housing, such that the plurality of LED chips are welded on the copper circuit layer.
